(19) United States
(12) Patent Application Publication
(10) Pub. No.: US 2025/0208362 A1
(43) Pub. Date: Jun. 26, 2025

(54) OPTICAL SEMICONDUCTOR ELEMENT AND METHOD OF MANUFACTURING OPTICAL SEMICONDUCTOR ELEMENT

(71) Applicant: Sumitomo Electric Industries, Ltd., Osaka (JP)

(72) Inventor: Takuo HIRATANI, Osaka-shi (JP)

(73) Assignee: Sumitomo Electric Industries, Ltd., Osaka (JP)

(21) Appl. No.: 18/987,928

(22) Filed: Dec. 19, 2024

(30) Foreign Application Priority Data
Dec. 22, 2023 (JP) 2023-216907

(51) Int. Cl. G02B 6/42; F21V 8/00; H01S 5/0235

(52) U.S. Cl. CPC G02B 6/4256; G02B 6/4236; G02B 6/0028; G02B 6/4296; H01S 5/0235

(57) ABSTRACT

An optical semiconductor element includes a substrate having a silicon layer, and a semiconductor element formed of III-V group compound semiconductor and bonded to the silicon layer. The silicon layer has a first waveguide, a second waveguide, a first recess, a second recess, a terrace, and a first slab portion. The first recess and the second recess are portions recessed from a surface of the first waveguide, a surface of the second waveguide, a surface of the terrace, and a surface of the first slab portion. The first recess and the terrace are arranged on either side of the first waveguide in an order of the first recess and the terrace. The semiconductor element has a protruding portion, a second slab portion, and a third slab portion.

### CROSS REFERENCE TO RELATED APPLICATIONS

This application claims priority based on Japanese Patent Application No. 2023-216907, filed on Dec. 22, 2023, and the entire contents of the Japanese patent application are incorporated herein by reference.

### TECHNICAL FIELD

The present disclosure relates to an optical semiconductor element and a method of manufacturing an optical semiconductor element.

### BACKGROUND

A hybrid optical semiconductor element can be formed by bonding a semiconductor element formed of a compound semiconductor and having an optical gain to a substrate such as a silicon on insulator (SOI) substrate (silicon photonics) on which a waveguide is formed (see non-patent literature 1: D. Huang, et al. “High-power sub-kHz linewidth lasers fully integrated on silicon” Optica Vol. 6, No. 6 745-752 (June 2019)). After the bonding, the semiconductor element is subjected to etching or the like. Light is transferred between the waveguide of silicon and the semiconductor element.

### SUMMARY

An optical semiconductor element according to the present disclosure includes a substrate having a silicon layer, and a semiconductor element formed of III-V group compound semiconductor and bonded to the silicon layer. The silicon layer has a first waveguide, a second waveguide, a first recess, a second recess, a terrace, and a first slab portion, the first recess and the second recess are portions recessed from a surface of the first waveguide, a surface of the second waveguide, a surface of the terrace, and a surface of the first slab portion, the first recess and the terrace are arranged on either side of the first waveguide in an order of the first recess and the terrace, the second recess and the terrace are arranged on either side of the second waveguide in an order of the second recess and the terrace, the first waveguide is connected to an end of the first slab portion, the second waveguide is connected to another end of the first slab portion, the first slab portion is connected to the terrace and located between the first recess and the second recess, the semiconductor element has a protruding portion, a second slab portion, and a third slab portion, the second slab portion is bonded to the first slab portion, the protruding portion protrudes from the second slab portion into the first waveguide, and the third slab portion is located on or over the second waveguide, the second recess, and the terrace.

### BRIEF DESCRIPTION OF THE DRAWINGS

FIG. 1 is a plan view illustrating an optical semiconductor element according to an embodiment.

FIG. 2A is an enlarged plan view of the vicinity of an MMI.

FIG. 2B is a plan view illustrating a substrate.

FIG. 3A is a cross-sectional view illustrating an optical semiconductor element.

FIG. 3B is a cross-sectional view illustrating an optical semiconductor element.

FIG. 4A is a cross-sectional view illustrating an optical semiconductor element.

FIG. 4B is a cross-sectional view illustrating an optical semiconductor element.

FIG. 5 is a cross-sectional view illustrating an optical semiconductor element.

FIG. 6 is a diagram illustrating the results of the calculation of transmittance.

FIG. 7 is a plan view illustrating a method of manufacturing an optical semiconductor element.

FIG. 8A is a cross-sectional view illustrating a method of manufacturing an optical semiconductor element.

FIG. 8B is a cross-sectional view illustrating a method of manufacturing an optical semiconductor element.

FIG. 9A is a cross-sectional view illustrating a method of manufacturing an optical semiconductor element.

FIG. 9B is a cross-sectional view illustrating a method of manufacturing an optical semiconductor element.

FIG. 10 is a plan view illustrating a method of manufacturing an optical semiconductor element.

FIG. 11A is a cross-sectional view illustrating a method of manufacturing an optical semiconductor element.

FIG. 11B is a cross-sectional view illustrating a method of manufacturing an optical semiconductor element.

FIG. 12A is a cross-sectional view illustrating a method of manufacturing an optical semiconductor element.

FIG. 12B is a cross-sectional view illustrating a method of manufacturing an optical semiconductor element.

FIG. 13 is a plan view illustrating a method of manufacturing an optical semiconductor element.

FIG. 14A is a cross-sectional view illustrating a method of manufacturing an optical semiconductor element.

FIG. 14B is a cross-sectional view illustrating a method of manufacturing an optical semiconductor element.

FIG. 15A is a cross-sectional view illustrating a method of manufacturing an optical semiconductor element.

FIG. 15B is a cross-sectional view illustrating a method of manufacturing an optical semiconductor element.

FIG. 16 is a plan view illustrating an optical semiconductor element according to a comparative example.

FIG. 17A is a cross-sectional view illustrating an optical semiconductor element.

FIG. 17B is a cross-sectional view illustrating an optical semiconductor element.

FIG. 17C is a cross-sectional view illustrating an optical semiconductor element.

### DETAILED DESCRIPTION

A trench is provided in the substrate. Etchants may enter the trench, and the semiconductor element may be etched from the bonding interface. In order to reduce damage to the semiconductor element, it is required to reduce unintended etching. In order to reduce the loss of light, it is required to increase the coupling efficiency between the waveguide and the semiconductor element. Thus, the objective is to provide an optical semiconductor element and a method of manufacturing an optical semiconductor element, which can reduce unintended etching and reduce loss of light.

### DESCRIPTION OF EMBODIMENTS OF PRESENT DISCLOSURE

First, the contents of embodiments of the present disclosure will be listed and explained.

(1) An optical semiconductor element according to an aspect of the present disclosure includes a substrate having a silicon layer, and a semiconductor element formed of III-V group compound semiconductor and bonded to the silicon layer. The silicon layer has a first waveguide, a second waveguide, a first recess, a second recess, a terrace, and a first slab portion, the first recess and the second recess are portions recessed from a surface of the first waveguide, a surface of the second waveguide, a surface of the terrace, and a surface of the first slab portion, the first recess and the terrace are arranged on either side of the first waveguide in an order of the first recess and the terrace, the second recess and the terrace are arranged on either side of the second waveguide in an order of the second recess and the terrace, the first waveguide is connected to an end of the first slab portion, the second waveguide is connected to another end of the first slab portion, the first slab portion is connected to the terrace and located between the first recess and the second recess, the semiconductor element has a protruding portion, a second slab portion, and a third slab portion, the second slab portion is bonded to the first slab portion, the protruding portion protrudes from the second slab portion into the first waveguide, and the third slab portion is located on or over the second waveguide, the second recess, and the terrace on either side of the second waveguide. Since the second recess is sealed by the first slab portion and the third slab portion, the etchant is kept from entering into the second recess. Unintended etching of the semiconductor element can be reduced. Since an MMI is formed, it is possible to reduce the loss of light.

(2) In the above (1), the first slab portion may have a larger width than the first waveguide and the second waveguide. Since the MMI is formed, it is possible to reduce the loss of light.

(3) In the above (1) or (2), the second slab portion may have a larger width than the protruding portion. Since the MMI is formed, it is possible to reduce the loss of light.

(4) In any one of the above (1) to (3), the first slab portion and the second slab portion may have a rectangular planar shape. Since the MMI is formed, it is possible to reduce the loss of light.

(5) In any one of the above (1) to (4), the first waveguide may have a first tapered portion, the first tapered portion may have a width increasing as a distance from the first slab portion decreases and decreasing as the distance from the first slab portion increases, the second waveguide may have a second tapered portion, and the second tapered portion may have a width increasing as a distance from the first slab portion decreases and decreasing as the distance from the first slab portion increases. Since the coupling efficiency between the substrate and the semiconductor element is increased, it is possible to reduce the loss of light.

(6) In any one of the above (1) to (5), the protruding portion may have a third tapered portion, and the protruding portion may have a width increasing as a distance from the second slab portion decreases and decreasing as the distance from the second slab portion increases. Since the mode shape of light gradually changes, it is possible to reduce the loss of light.

(7) In any one of the above (1) to (6), the second slab portion, the third slab portion, and the protruding portion of the semiconductor element may be formed of indium phosphide. The semiconductor element is processed by wet-etching. The etchant is kept from entering into the second recess. Unintended etching of the semiconductor element can be reduced.

(8) In any one of the above (1) to (7), the optical semiconductor element may further include an insulating film covering the silicon layer and the semiconductor element. The insulating film covers the first waveguide and the MMI and functions as a cladding layer. It is possible to reduce the loss of light.

(9) A method of manufacturing an optical semiconductor element, the method includes: bonding a semiconductor element to a silicon layer of a substrate, the semiconductor element being formed of III-V group compound semiconductor; and performing wet-etching on the bonded semiconductor element. The silicon layer has a first waveguide, a second waveguide, a first recess, a second recess, a terrace, and a first slab portion, the first recess and the second recess are portions recessed from a surface of the first waveguide, a surface of the second waveguide, a surface of the terrace, and a surface of the first slab portion, the first recess and the terrace are arranged on either side of the first waveguide in an order of the first recess and the terrace, the second recess and the terrace are arranged on either side of the second waveguide in an order of the second recess and the terrace, the first waveguide is connected to an end of the first slab portion, the second waveguide is connected to another end of the first slab portion, the first slab portion is connected to the terrace and located between the first recess and the second recess, the bonding bonds the semiconductor element to the first waveguide, the first slab portion, the second waveguide, and the terrace on either side of the first waveguide and the second waveguide, the performing includes forming a protruding portion, a second slab portion, and a third slab portion in the semiconductor element, the second slab portion is bonded to the first slab portion, the protruding portion protrudes from the second slab portion into the first waveguide, and the third slab portion is located on or over the second waveguide, the second recess, and the terrace on either side of the second waveguide. The second recess is sealed by the first slab portion and the third slab portion. The etchant is kept from entering into the second recess. Unintended etching of the semiconductor element can be reduced. Since the MMI is formed, it is possible to reduce the loss of light.

### DETAILS OF EMBODIMENTS OF PRESENT DISCLOSURE

Specific examples of an optical semiconductor element and a method of manufacturing an optical semiconductor element according to embodiments of the present disclosure will be described below with reference to the drawings. It is noted that, the present disclosure is not limited to these examples, but is defined by the scope of the claims, and is intended to include all modifications within the meaning and scope equivalent to the scope of the claims.

### EMBODIMENT

### (Optical Semiconductor Element)

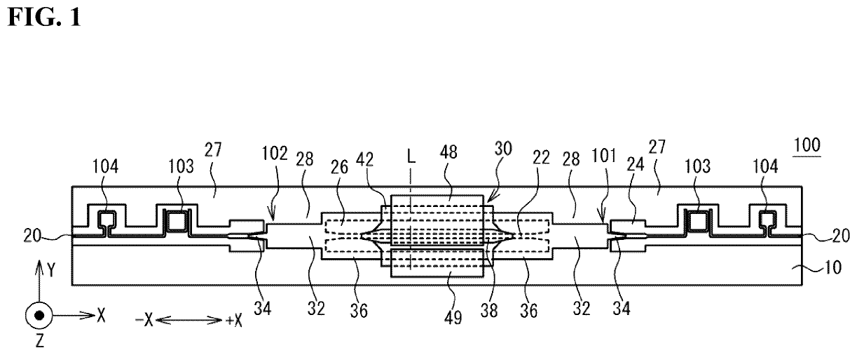

FIG. 1 is a plan view illustrating an optical semiconductor element 100 according to an embodiment. Optical semiconductor element 100 is a hybrid type wavelength tunable laser diode, and includes a substrate 10 and a semiconductor element 30. Semiconductor element 30 has an optical gain and is bonded to one surface of substrate 10. The Z-axis direction is parallel to a direction of a normal line of the upper surface of substrate 10. The X-axis direction is a direction parallel to the waveguide. One direction along the X-axis is defined as a +X direction. The direction opposite to the +X direction is defined as a −X direction. The Y-axis direction is orthogonal to the X-axis direction and the Z-axis direction.

Optical semiconductor element 100 includes a multi-mode interferometer (MMI) 101, an MMI 102, two ring resonators 103, and two loop mirrors 104. Loop mirror 104, ring resonator 103, MMI 102, semiconductor element 30, MMI 101, ring resonator 103, and loop mirror 104 are arranged in this order from the −X direction to the +X direction. A laser resonator is formed by these components.

Each of MMI 101 and MMI 102 is a one input one output MMI, and is formed by substrate 10 and semiconductor element 30. Ring resonator 103 and loop mirror 104 are provided on substrate 10.

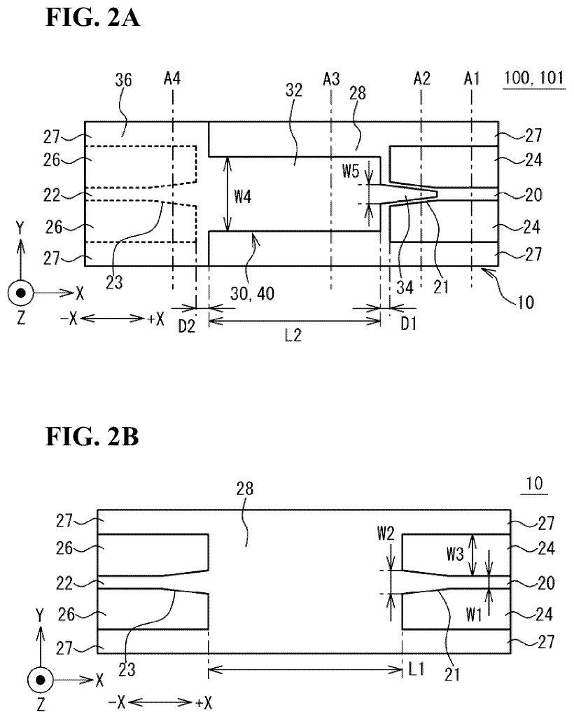

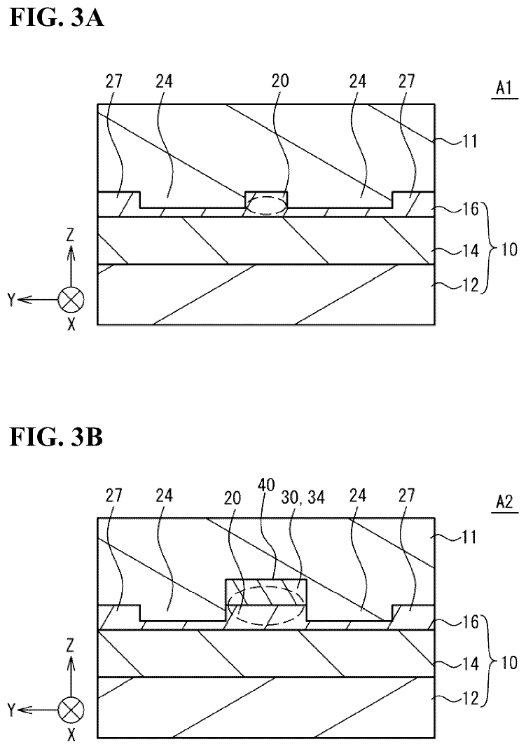

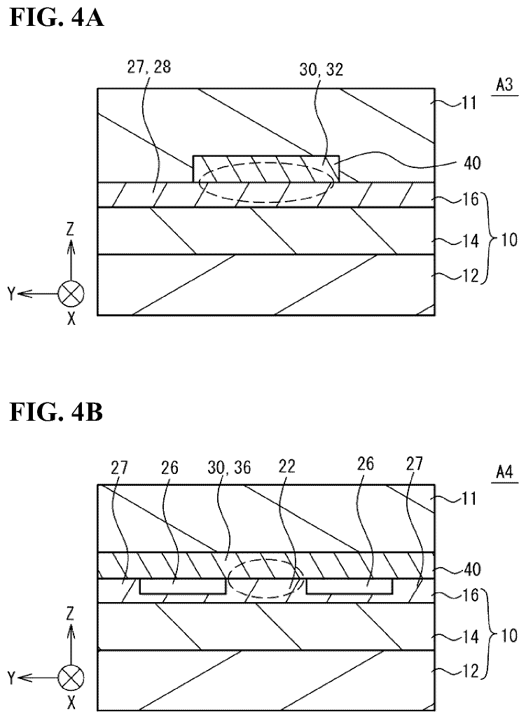

FIG. 2A is an enlarged plan view of the vicinity of MMI 101. FIG. 2B is a plan view illustrating substrate 10, with semiconductor element 30 removed from FIG. 2A. FIG. 3A to FIG. 4B are cross-sectional views illustrating optical semiconductor element 100, showing cross sections taken along a line A1, a line A2, a line A3, and a line A4 of FIG. 2A, respectively. The light distribution is illustrated by dashed lines in FIG. 3A to FIG. 4B.

As shown in FIG. 3A to FIG. 4B, substrate 10 is a silicon on insulator (SOI) substrate, and includes a substrate 12, a BOX layer 14, and a silicon (Si) layer 16 stacked in order in the Z-axis positive direction. Substrate 12 is formed of, for example, Si. Box layer 14 is formed of, for example, silicon oxide (SiO₂). The thickness of BOX layer 14 is, for example, 3 μm. The thickness of silicon layer 16 is, for example, 220 nm. The upper surface of substrate 10 and the surface of semiconductor element 30 are covered with an insulating film 11. Insulating film 11 is formed of SiO₂ having a thickness of 1 μm, for example. The refractive index of silicon layer 16 is 3.45. The refractive index of BOX layer 14 and insulating film 11 is 1.45, which is lower than that of silicon layer 16. A functional portion such as a waveguide is provided in silicon layer 16 of substrate 10.

As shown in FIG. 2A and FIG. 2B, substrate 10 includes a waveguide 20 (first waveguide), a waveguide 22 (second waveguide), a recess 24 (first recess), a recess 26 (second recess), a terrace 27, and a slab portion 28 (first slab portion).

Waveguide 20, slab portion 28, and waveguide 22 are arranged in this order from the +X side toward the −X side. Waveguide 20 is connected to one end (+X side end) of slab portion 28. Waveguide 22 is connected to the other end (−X side end) of slab portion 28. Waveguide 20 and waveguide 22 are parallel to the X-axis direction.

Waveguide 20 has a tapered portion 21 (first tapered portion). Waveguide 22 has a tapered portion 23 (second tapered portion). Tapered portion 21 and tapered portion 23 have widths increasing as distances from slab portion 28 decreases and decreasing as the distances from slab portion 28 increases.

In the Y-axis direction, recess 24 and terrace 27 are provided on either side of waveguide 20 in an order of recess 24 and terrace 27. That is, recess 24 is arranged adjacent to waveguide 20. Terrace 27 is arranged opposite to waveguide 20 of recess 24. Recess 26 and terrace 27 are provided on either side of waveguide 22 in an order of recess 26 and terrace 27. Recess 24 extends along waveguide 20 and has a taper shape corresponding to tapered portion 21 of waveguide 20. Recess 26 extends along waveguide 22 and has a taper shape corresponding to tapered portion 23 of waveguide 22.

Slab portion 28 is located between recess 24 and recess 26 in the X-axis direction, and is connected to two terraces 27 on either side of the waveguides. Recess 24 and recess 26 are blocked by slab portion 28. Slab portion 28 has a rectangular planar shape. Slab portion 28 is plate-shaped and has no groove and no hole.

A width W1 at the tip of waveguide 20 shown in FIG. 2B is, for example, 400 nm. A width W2 of the portion of tapered portion 21 connected to slab portion 28 is, for example, 2.4 μm. A width W3 of recess 24 is, for example, 1 μm to 10 μm, and may be 2 μm, 3 μm, 4 μm, or the like. The dimensions of waveguide 22 may be the same as or different from the dimensions of waveguide 20. The dimensions of recess 26 may be the same as or different from the dimensions of recess 24. A length L1 of a slab portion 28 in the X-axis direction is, for example, 37.8 μm.

As shown in FIG. 3A and FIG. 3B, waveguide 20 and terrace 27 are portions of silicon layer 16 that protrude in the Z-axis direction (upward) from recess 24. The surface of waveguide 20 is located at the same height as the surface of terrace 27. Recess 24 is a portion recessed from the surfaces of waveguide 20 and terrace 27. As shown in FIG. 4B, the surface of waveguide 22 is located at the same height as the surface of terrace 27. Recess 26 is a portion recessed from the surfaces of waveguide 22 and terrace 27. Silicon layer 16 serves as the bottom surfaces of recesses 24 and 26. The thickness of silicon layer 16 in the recess is, for example, 30 nm. Recess 24 and recess 26 may extend to the middle of silicon layer 16 in the Z-axis direction, or may extend to BOX layer 14 through silicon layer 16. Insulating film 11 is embedded in recess 24 and recess 26.

As shown in FIG. 4A, the surface of slab portion 28 is located at the same height as the surface of terrace 27. Slab portion 28 is integrated with terrace 27 and extends parallel to the XY plane and forms the surface of silicon layer 16.

As shown in FIG. 1, semiconductor element 30 includes two slab portions 32 (second slab portions), two protruding portions 34, two slab portions 36 (third slab portions), a mesa 38, an electrode 48, and an electrode 49. Protruding portion 34, slab portion 32, slab portion 36, mesa 38, slab portion 36, slab portion 32, and protruding portion 34 are arranged in order from the +X side toward the −X side. Slab portion 32 and slab portion 36 are plate-shaped.

As shown in FIG. 2A, slab portion 32 and slab portion 36 have a rectangular planar shape. A width W4 of slab portion 32 is, for example, 4 μm. A length L2 of slab portion 32 in the X-axis direction is smaller than length L1 of slab portion 28 of silicon layer 16, and is, for example, 33.8 μm. Slab portion 32 is located on slab portion 28 of silicon layer 16 and does not extend outward from slab portion 28. Slab portion 28 extends from a position overlapping slab portion 32 to the outside of slab portion 32. A distance D1 from the end of slab portion 32 to the end of slab portion 28 is, for example, 2 μm. As shown in FIG. 2A and FIG. 4A, slab portion 32 is bonded to slab portion 28 of substrate 10.

As shown in FIG. 2A, protruding portion 34 of semiconductor element 30 extends parallel to the X-axis, protrudes from slab portion 32 into waveguide 20 in the plan view, and is located on tapered portion 21 of waveguide 20. Protruding portion 34 has a taper shape. Protruding portion 34 has a width increasing as a distance from slab portion 32 decreases and decreasing as the distance from slab portion 32 increases. A width W5 of protruding portion 34 at the position where protruding portion 34 is connected to slab portion 32 is, for example, 2 μm. As shown in FIG. 2A and FIG. 3B, protruding portion 34 is bonded to waveguide 20 and slab portion 28 of substrate 10.

As shown in FIG. 2A, slab portion 36 is located opposite to protruding portion 34 of slab portion 32 in the X-axis direction. Slab portion 36 is located on or over waveguide 22, recesses 26 on both sides of waveguide 22, terraces 27, and slab portion 28, and is bonded to waveguide 22, terraces 27, and slab portion 28. A distance D2 from recess 26 of silicon layer 16 to the end of slab portion 36 is, for example, 2 μm.

Protruding portion 34 does not extend outward from waveguide 20, and is located inside waveguide 20. Waveguide 20 extends outward from under protruding portion 34 to the outside of protruding portion 34.

As shown in FIG. 1, MMI 102 has a similar configuration to MMI 101. Waveguide 22, recess 26, and terrace 27 extend from MMI 101 to MMI 102. Recess 26 is located between waveguide 22 and terrace 27. Slab portion 36 of semiconductor element 30 extends from MMI 101 to MMI 102, and is located on or over recess 26, terrace 27, and waveguide 22. Recess 26 is sealed by slab portion 28 and slab portion 36.

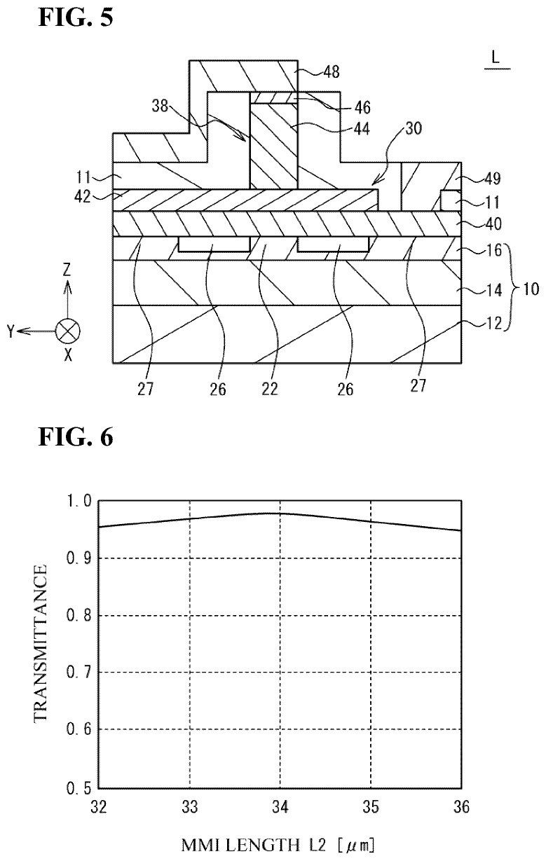

FIG. 5 is a cross-sectional view illustrating optical semiconductor element 100, showing cross section taken along line L of FIG. 1. Semiconductor element 30 includes a cladding layer 40, an active layer 42, a cladding layer 44, and a contact layer 46. Cladding layer 40 is contact with silicon layer 16 to form protruding portion 34, slab portion 32, and slab portion 36 shown in FIG. 2A.

As shown in FIG. 5, active layer 42, cladding layer 44, and contact layer 46 are stacked in this order on cladding layer 40. Active layer 42 is located on or over waveguide 22, recess 26, and terrace 27. Cladding layer 44 and contact layer 46 are stacked to active layer 42 and located over waveguide 22 to form mesa 38.

Insulating film 11 covers the upper surface of cladding layer 40, the upper surface and the side surface of active layer 42, and the side surfaces of mesa 38. Insulating film 11 has an opening portion on active layer 42 and also has an opening portion on mesa 38. Electrode 48 is a p-type electrode and extends from the top of mesa 38 to the outside of mesa 38. Electrode 48 is electrically connected to contact layer 46 through the opening portion of insulating film 11. Electrode 49 is spaced apart from mesa 38 and electrically connected to cladding layer 40 through the opening portion of insulating film 11.

As shown in FIG. 1, the end of mesa 38 in the X-axis direction may have a taper shape. An end of active layer 42 in the X-axis direction may have a taper shape. The taper shape is provided, and thus coupling efficiency is increased.

Cladding layer 40 is formed of, for example, n-type indium phosphide (n-InP) having a thickness of 0.4 μm. Active layer 42 has a multiple quantum well (MQW) and includes a barrier layer and a well layer. The plurality of barrier layers and the plurality of well layers are alternately stacked. The barrier layers and the well layers are formed of, for example, gallium indium arsenide phosphide (GaInAsP). Cladding layer 44 is formed of, for example, p-type indium phosphide (p-InP). Contact layer 46 is formed of, for example, p-type gallium indium arsenide (p-GaInAs). The semiconductor layer of semiconductor element 30 may be formed of a III-V group compound semiconductor other than the above.

Electrode 48 and electrode 49 are formed of a metal. Electrode 48 is formed of a stacked body in which titanium (Ti), platinum (Pt), and gold (Au) are stacked in order from a position closer to mesa 38, for example. Electrode 49 is formed of, for example, an alloy of gold, germanium, and nickel (AuGeNi).

A voltage is applied to semiconductor element 30 by using electrode 48 and electrode 49, and carriers are injected into active layer 42. Active layer 42 has an optical gain and generates light by carrier injection. The wavelength of the light is, for example, 1.5 μm. Semiconductor element 30 and substrate 10 are optically coupled by evanescent optical coupling. The light generated in semiconductor element 30 propagates through waveguide 22 and is transferred to waveguides 20 in MMI 101 and MM 102. The light resonates in ring resonator 103 and is reflected by loop mirror 104. The reflected light propagates toward semiconductor element 30, and is transferred from waveguide 20 to waveguide 22 in MMI 101 and MMI 102. The light is repeatedly reflected, and thus laser oscillation occurs.

The diameter of one of two ring resonators 103 is different from the diameter of the other. The oscillation wavelength is determined by the vernier effect of two ring resonators 103. The transmittance of one of two loop mirrors 104 is higher than the transmittance of the other. A part of the laser light is transmitted through loop mirror 104 and emitted to the outside of optical semiconductor element 100.

In FIG. 3A to FIG. 4B, the shape of the light is schematically showed by an ellipse with a dashed line. The mode of the light is defined by waveguide 20 and waveguide 22, and in the MMI by slab portion 32. Light is intensively distributed in waveguide 20 and waveguide 22. In the MMI, light is distributed widely to the extent of the width of slab portion 32.

When light is input to the MMI and when light is output from the MMI, the mode of the light is converted. By adjusting the lengths and widths of slab portion 28 and slab portion 32, the mode of the light can be controlled. The same mode is imaged at the output portion and the input portion of the MMI. For example, a single mode propagates through waveguide 20. When light is input from waveguide 20 to MMI 101, a multimode is generated. When light is output from MMI 101 to waveguide 22, the mode is converted into a single mode. The same mode propagates through waveguide 20 and waveguide 22. Even in MMI 102, the input and output mode shapes can be made close to the same. The loss of light in optical semiconductor element 100 can be reduced.

FIG. 6 is a diagram illustrating the results of the calculation of transmittance. The horizontal axis represents an MMI length. The MMI length is length L2 of slab portion 32 of semiconductor element 30 shown in FIG. 2A. The vertical axis represents the transmittance of light in the MMI. The wavelength of the light is 1.5 μm. The transmittance is calculated by changing length L2 from 32 μm to 36 μm. The transmittance is 0.9 or more when length L2 is any value from 32 μm to 36 μm. The loss of light in the MMI is reduced.

### (Manufacturing Method)

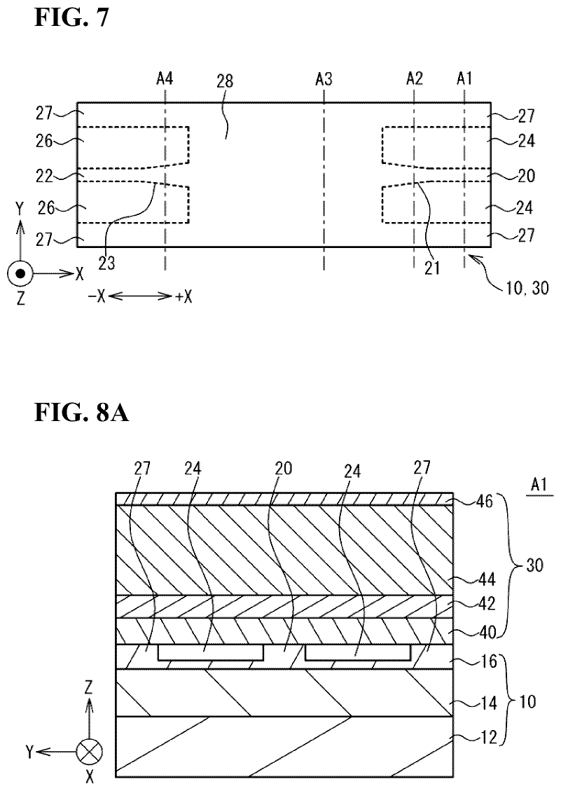

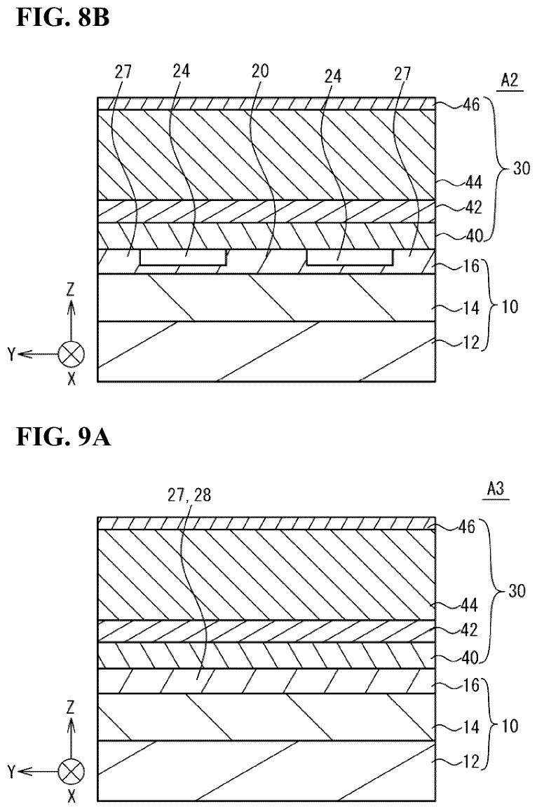

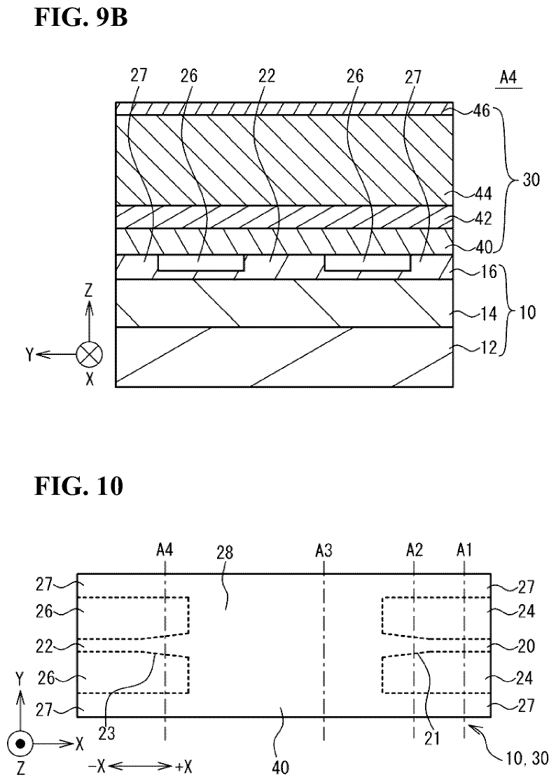

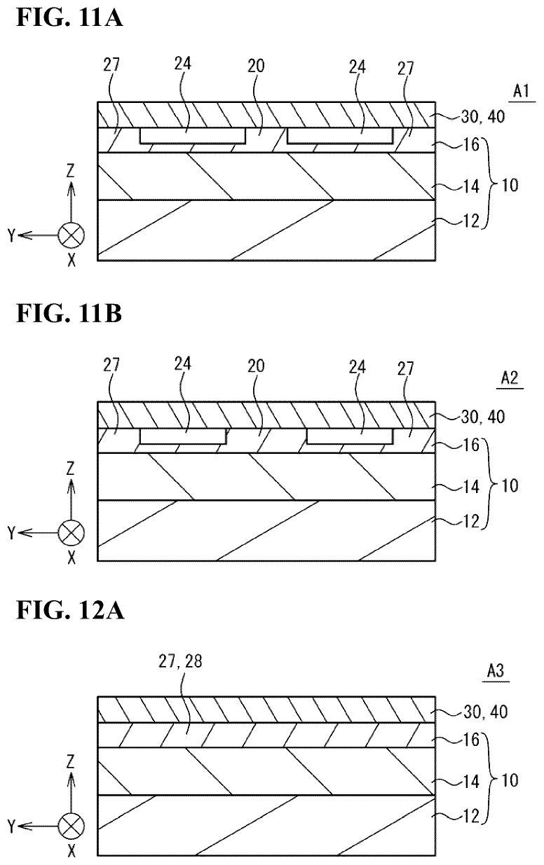

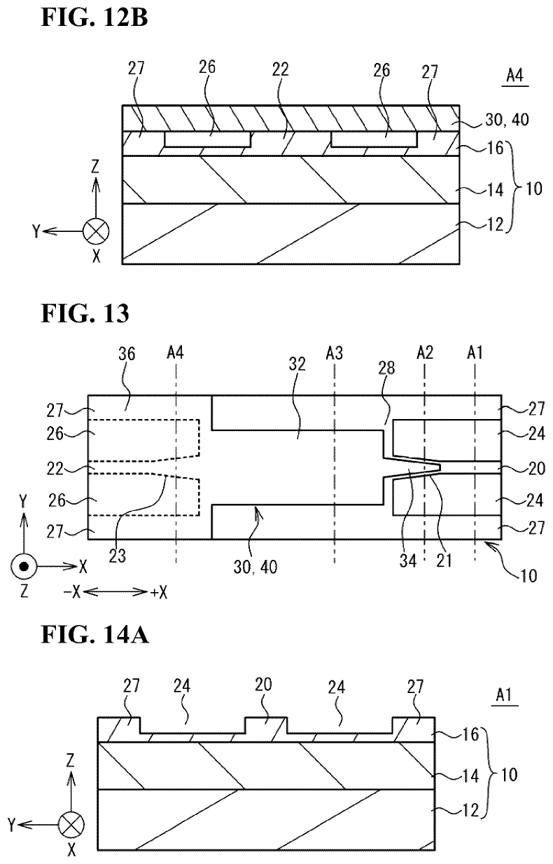

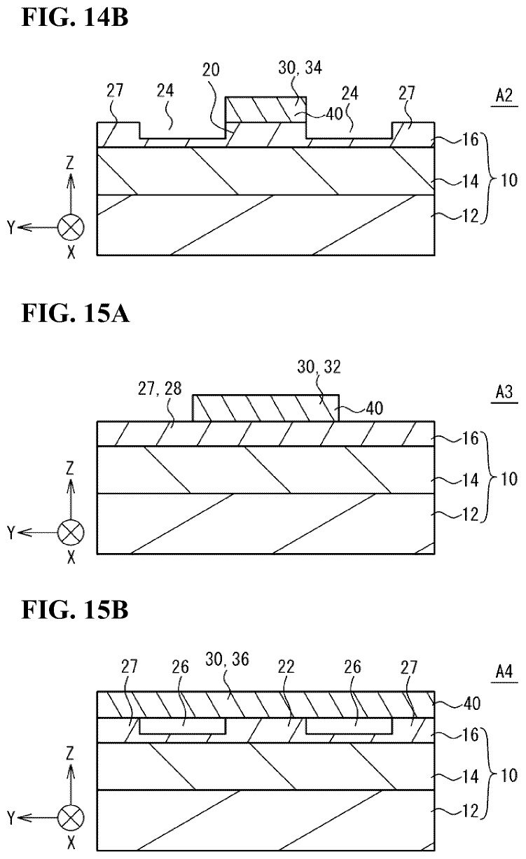

FIG. 7, FIG. 10, and FIG. 13 are plan views illustrating a method of manufacturing optical semiconductor element 100. FIG. 8A to FIG. 9B are cross-sectional views illustrating a method of manufacturing optical semiconductor element 100, showing cross sections taken along a line A1, a line A2, a line A3, and a line A4 of FIG. 7, respectively. FIG. 11A to FIG. 12B are cross-sectional views illustrating a method of manufacturing optical semiconductor element 100, showing cross sections taken along a line A1, a line A2, a line A3, and a line A4 of FIG. 10, respectively. FIG. 14A to FIG. 15B are cross-sectional views illustrating a method of manufacturing optical semiconductor element 100, showing cross sections taken along a line A1, a line A2, a line A3, and a line A4 of FIG. 13, respectively.

In a step prior to FIG. 7, for example, dry etching is performed on silicon layer 16 of substrate 10. The portions exposed from a mask (not shown) are etched to form recess 24 and recess 26. The portion covered with the mask (not shown) is not etched. As in FIG. 2B, waveguide 20 and waveguide 22, terrace 27, and slab portion 28 are formed.

On an InP wafer different from the silicon wafer (substrate 10), contact layer 46, cladding layer 44, active layer 42, and cladding layer 40 are epitaxially grown in order by metal organic chemical vapor deposition (MOCVD) or the like. After the film formation, the wafer is diced to form semiconductor element 30. Semiconductor element 30 immediately after dicing is a rectangular parallelepiped, and does not have the slab portion, protruding portion 34, and the like.

As shown in FIG. 7 to FIG. 9B, semiconductor element 30 is bonded to the upper surface of substrate 10. One surface of silicon layer 16 and cladding layer 40 of semiconductor element 30 are irradiated with plasma to activate these surfaces. Cladding layer 40 is brought into contact with the surface of silicon layer 16, and semiconductor element 30 is bonded to silicon layer 16. For example, the bonding strength is increased by pressurization, heat treatment, or the like. Semiconductor element 30 covers, for example, the entire surface of silicon layer 16, and is located on or over waveguide 20, waveguide 22, recess 24, recess 26, terrace 27, and slab portion 28. After the bonding, the InP substrate is removed by wet-etching. The semiconductor layers from contact layer 46 to cladding layer 40 remain.

As shown in FIG. 10 to FIG. 12B, active layer 42 is removed from contact layer 46 of semiconductor element 30 by wet-etching. Cladding layer 40 remains. In the cross-section at position L shown in FIG. 5, layers from contact layer 46 to active layer 42 remains, and mesa 38 is formed.

As shown in FIG. 13 to FIG. 15B, for example, wet-etching is performed to form slab portion 32, slab portion 36, and protruding portion 34. For example, a hydrochloric acid-based chemical solution is used as the etchant. The portion of semiconductor element 30 protected by a mask (not shown) is not etched. The portions exposed from the mask are removed by etching.

In the wet-etching step, the etchant enters recess 24. Slab portion 28 is provided between recess 24 and recess 26, and recess 26 is closed by slab portion 28 and slab portion 36. Since the etchant is kept from entering into recess 26, semiconductor element 30 is kept from being etched from the bonding interface.

Insulating film 11 is formed by a plasma enhanced chemical vapor deposition method (PECVD) or the like as shown in FIG. 3A to FIG. 4B. Electrode 48 and electrode 49 are formed by vacuum deposition. Optical semiconductor element 100 is formed by the above steps.

### COMPARATIVE EXAMPLE

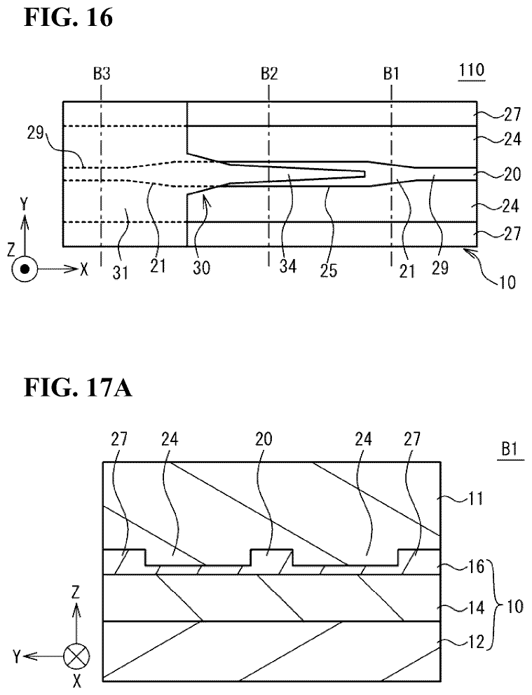

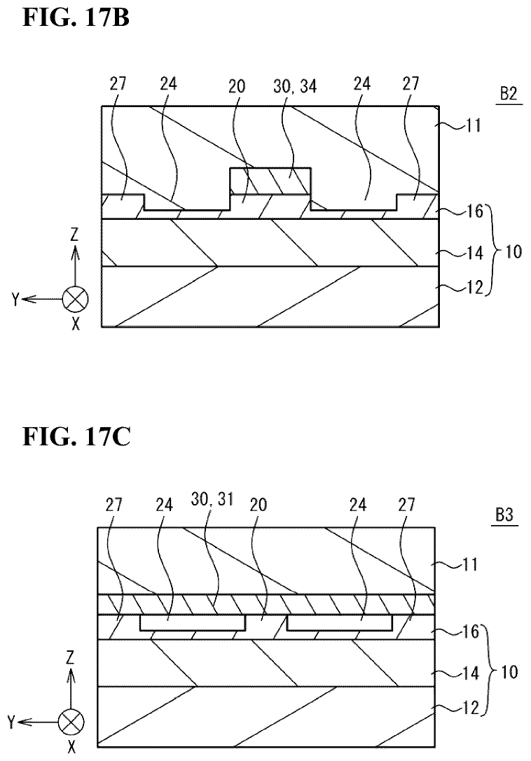

FIG. 16 is a plan view illustrating an optical semiconductor element 110 according to a comparative example. FIG. 17A to FIG. 17C are cross-sectional views illustrating optical semiconductor element 110, showing cross sections taken along a line B1, a line B2, and a line B3 of FIG. 16, respectively. The description of the same configuration as that of the embodiment will be omitted.

As shown in FIG. 16 to FIG. 17C, substrate 10 has waveguide 20, recess 24, and terrace 27, but does not have the slab portion. Waveguide 20, recess 24, and terrace 27 extend from one end to another end of substrate 10 in the X-axis direction. Waveguide 20 has tapered portion 21, a portion 29, and a portion 25. In the X-axis direction, portion 29, tapered portion 21, portion 25, tapered portion 21, and portion 29 are arranged in this order. Portion 25 is wider than portion 29. Tapered portion 21 is connected to portion 29 and portion 25.

Semiconductor element 30 includes a slab portion 31 and protruding portion 34. Protruding portion 34 protrudes from slab portion 31 in the X-axis direction and is located on portion 25 of waveguide 20. Slab portion 31 is located on or over waveguide 20, recess 24 and terrace 27.

Recess 24 is located on either side of waveguide 20 and extends from the outside of semiconductor element 30 under semiconductor element 30. In the step of performing wet-etching on semiconductor element 30, a liquid such as an etchant enters into recess 24 and flows under semiconductor element 30. Semiconductor element 30 is etched from the lower surface (bonding interface), and thus semiconductor element 30 is damaged. The bonding strength of semiconductor element 30 to substrate 10 is reduced.

According to the present embodiment, silicon layer 16 of substrate 10 has waveguide 20 and waveguide 22, recess 24 and recess 26, and slab portion 28. Slab portion 28 is located between recess 24 and recess 26 to block recess 24 and recess 26. Semiconductor element 30 is bonded to silicon layer 16 and has slab portion 32 and slab portion 36. Slab portion 36 is located on or over waveguide 22, recess 26, and terrace 27. Recess 26 is sealed by slab portion 28 and slab portion 36. A liquid such as an etchant is less likely to enter into recess 26. Unintended etching of semiconductor element 30 can be reduced.

Semiconductor element 30 is formed of a III-V group compound semiconductor. After the bonding, wet-etching is performed to form protruding portion 34, slab portion 32, and slab portion 36. Semiconductor element 30 includes a cladding layer of InP, active layer 42 of InGaAsP, and contact layer 46 of InGaAs. In the wet-etching, an etchant suitable for these semiconductors is used. For example, a hydrochloric acid-based solution is used as the etchant. Since the etchant is kept from entering into recess 26 by slab portion 28 and slab portion 36, unintended etching of semiconductor element 30 can be reduced.

When slab portion 32 extends over recess 24, slab portion 32 is etched by the etchant that enters recess 24. As in FIG. 2A, slab portion 32 does not extend over recess 24, but is located on slab portion 28 of silicon layer 16. Slab portion 32 is not easily etched from the bonding interface. Distance D1 from slab portion 32 to recess 24 may be 2 μm or more or 2 μm or less. Distance D2 from the end of slab portion 36 to recess 26 may be 2 μm or more or 2 μm or less. Slab portion 36 covers entire recess 26, and recess 26 is not exposed from slab portion 36, whereby the etchant is kept from entering into recess 26.

Silicon layer 16 and semiconductor element 30 form MMI 101 and MMI 102. As shown in FIG. 2A, waveguide 20 and waveguide 22 extend from slab portion 28. Slab portion 32 of semiconductor element 30 is bonded to slab portion 28. Protruding portion 34 protrudes from slab portion 32 into waveguide 20. Light of a single mode propagates through waveguide 20. When light inputs slab portion 28, the mode is converted to multimode. When light is output from the MMI to waveguide 22, the light of a single mode is imaged and propagates through waveguide 22. By making the mode shapes of light on the input side and the output side close to the same, it is possible to reduce the loss of light.

The mode shape is controlled by adjusting the widths and lengths of the waveguide and slab portion. The mode shape at the time of input to the MMI and the mode shape at the time of output from the MMI can be made close to the same. As shown in FIG. 6, when MMI length L2 is set to 32 μm to 36 μm, the transmittance is high and the loss of light is reduced. This is because the mode shapes are close to the same.

Slab portion 28 of silicon layer 16 has a larger width than waveguides 20 and 22. Slab portion 32 of semiconductor element 30 has a larger width than protruding portion 34. MMI 101 and MMI 102 are formed. The modes are converted at the input and output of light to the MMI. By adjusting lengths L2 of slab portions 32, the mode shape at the time of input to the MMI and the mode shape at the time of output from the MMI are made closer to each other. The coupling efficiency is increased, and it is possible to reduce the loss of light.

Slab portion 28 and slab portion 32 have a rectangular planar shape. MMI 101 and MMI 102 are formed. It is possible to reduce the loss of light.

Waveguide 20 has tapered portion 21, and waveguide 22 has tapered portion 23. Since the mode shape of light gradually changes, it is possible to reduce the loss of light.

Protruding portion 34 of semiconductor element 30 has a tapered portion (third tapered portion), and entire protruding portion 34 has a taper shape. The light gradually transfers to semiconductor element 30. Since the coupling efficiency between semiconductor element 30 and silicon layer 16 is improved, it is possible to reduce the loss of light.

Insulating film 11 covers silicon layer 16 and semiconductor element 30 of substrate 10. Since insulating film 11 functions as a cladding layer, it is possible to reduce the loss of light.

Optical semiconductor element 100 of FIG. 1 is a wavelength tunable laser diode. Optical semiconductor element 100 may be an optical device other than the wavelength tunable laser diode.

Although the embodiments of the present disclosure have been described in detail, the present disclosure is not limited to the specific embodiments, and various modifications and changes can be made within the scope of the gist of the present disclosure described in the claims.

What is claimed is:

1. An optical semiconductor element comprising:
a substrate having a silicon layer; and
a semiconductor element formed of III-V group compound semiconductor and bonded to the silicon layer, wherein
the silicon layer has a first waveguide, a second waveguide, a first recess, a second recess, a terrace, and a first slab portion,
the first recess and the second recess are portions recessed from a surface of the first waveguide, a surface of the second waveguide, a surface of the terrace, and a surface of the first slab portion,
the first recess and the terrace are arranged on either side of the first waveguide in an order of the first recess and the terrace,
the second recess and the terrace are arranged on either side of the second waveguide in an order of the second recess and the terrace,
the first waveguide is connected to an end of the first slab portion,
the second waveguide is connected to another end of the first slab portion,
the first slab portion is connected to the terrace and located between the first recess and the second recess,
the semiconductor element has a protruding portion, a second slab portion, and a third slab portion,
the second slab portion is bonded to the first slab portion,
the protruding portion protrudes from the second slab portion into the first waveguide, and
the third slab portion is located on or over the second waveguide, the second recess, and the terrace.

2. The optical semiconductor element according to claim 1, wherein the first slab portion has a larger width than the first waveguide and the second waveguide.

3. The optical semiconductor element according to claim 1, wherein the second slab portion has a larger width than the protruding portion.

4. The optical semiconductor element according to claim 1, wherein the first slab portion and the second slab portion have a rectangular planar shape.

5. The optical semiconductor element according to claim 1, wherein
the first waveguide has a first tapered portion,
the first tapered portion has a width increasing as a distance from the first slab portion decreases and decreasing as the distance from the first slab portion increases,
the second waveguide has a second tapered portion, and
the second tapered portion has a width increasing as a distance from the first slab portion decreases and decreasing as the distance from the first slab portion increases.

6. The optical semiconductor element according to claim 1, wherein
the protruding portion has a third tapered portion, and
the protruding portion has a width increasing as a distance from the second slab portion decreases and decreasing as the distance from the second slab portion increases.

7. The optical semiconductor element according to claim 1, wherein the second slab portion, the third slab portion, and the protruding portion of the semiconductor element are formed of indium phosphide.

8. The optical semiconductor element according to claim 1, further comprising an insulating film covering the silicon layer and the semiconductor element.

9. A method of manufacturing an optical semiconductor element, the method comprising:
bonding a semiconductor element to a silicon layer of a substrate, the semiconductor element being formed of III-V group compound semiconductor; and
performing wet-etching on the bonded semiconductor element, wherein
the silicon layer has a first waveguide, a second waveguide, a first recess, a second recess, a terrace, and a first slab portion,
the first recess and the second recess are portions recessed from a surface of the first waveguide, a surface of the second waveguide, a surface of the terrace, and a surface of the first slab portion,
the first recess and the terrace are arranged on either side of the first waveguide in an order of the first recess and the terrace,
the second recess and the terrace are arranged on either side of the second waveguide in an order of the second recess and the terrace,
the first waveguide is connected to an end of the first slab portion,
the second waveguide is connected to another end of the first slab portion,
the first slab portion is connected to the terrace and located between the first recess and the second recess,
the bonding bonds the semiconductor element to the first waveguide, the first slab portion, the second waveguide, and the terrace on either side of the first waveguide and the second waveguide,
the performing includes forming a protruding portion, a second slab portion, and a third slab portion in the semiconductor element,
the second slab portion is bonded to the first slab portion,
the protruding portion protrudes from the second slab portion into the first waveguide, and
the third slab portion is located on or over the second waveguide, the second recess, and the terrace.
